(19) United States
(12) Patent Application Publication
(10) Pub. No.: US 2024/0218985 A1
(43) Pub. Date: Jul. 4, 2024

(54) DOSING UNIT FOR GENERATING A MIXED GAS

(71) Applicant: AVL LIST GMBH, GRAZ (AT)

(72) Inventor: MICHAEL BUCHNER, GRAZ (AT)

(73) Assignee: AVL LIST GMBH, GRAZ (AT)

(21) Appl. No.: 17/913,830

(22) PCT Filed: Mar. 26, 2021
(86) PCT No.: PCT/AT2021/060103

§ 371 Date: Sep. 23, 2022

(30) Foreign Application Priority Data
Mar. 27, 2020 (AT) A50250/2020

(51) Int. Cl. F17D 3/12; H01M 8/04089

(52) U.S. Cl. CPC F17D 3/12; H01M 8/04089

(57) ABSTRACT

A metering unit for generating a mixed gas. The metering unit includes a main gas source, a main gas line, a main gas branch line with a first mass flow controller, a supplementary gas source, a supplementary gas line with a second mass flow controller, a storage tank connected to the main gas branch line and the supplementary gas line to store the main and supplementary gas as the mixed gas, a vent line with a valve to discharge the mixed gas from the storage tank, a mixed gas line with a third mass flow controller to convey the mixed gas from the first storage tank, and a mixing zone fluidically connected to the mixed and main gas lines so that the main and mixed gas flow into the mixing line to provide a measuring gas. The mixing zone leads the measuring gas to a consumer via an outlet line.

### CROSS REFERENCE TO PRIOR APPLICATIONS

This application is a U.S. National Phase application under 35 U.S.C. § 371 of International Application No. PCT/AT2021/060103, filed on Mar. 26, 2021 and which claims benefit to Austrian Patent Application No. A50250/2020, filed on Mar. 27, 2020. The International Application was published in German on Sep. 30, 2021 as WO 2021/189093 A1 under PCT Article 21(2).

### FIELD

The present invention relates to a dosing/metering unit for generating a mixed gas, comprising a main gas source, a main gas branch line, via which main gas can be conveyed from the main gas source and in which a first mass flow controller is arranged, a supplementary gas source, a supplementary gas line, via which supplementary gas can be conveyed and in which a second mass flow controller is arranged, a storage tank, which is connected to the main gas branch line and the supplementary gas line and in which a mixed gas from the main gas and the supplementary gas is stored, a vent line, via which the mixed gas can be discharged from the storage tank, a check valve or pressure relief valve with a defined opening pressure, which is arranged in the vent line, and a mixed gas line, via which the mixed gas can be conveyed out of the storage tank and in which a third mass flow controller is arranged.

### BACKGROUND

Such metering units are used, for example, to generate a mixed gas stream for testing fuel cells in which one or more harmful gases are mixed with hydrogen to subsequently determine what effect the harmful gases have on a fuel cell stack. This can also be used on the cathode side to simulate the effect of different gas compositions of the oxygen-containing air stream. A precisely dosed defined mass flow of the mixed gas is fed to the fuel cell stack for this purpose.

Such a mixing unit for the production of a mixture of hydrogen and monophosphane is described, for example, in CN 209406081 U. The monophosphane and the hydrogen are here fed in a controlled manner via a diaphragm valve, a check valve, and a mass flow sensor, to a storage tank, where they are stored. A vent line, in which a pressure relief valve is arranged, leads from the storage tank to the outside. A line furthermore branches off from the storage tank in which a gas analyzer is arranged.

Only rather imprecise mixing ratios can be achieved with the above-described setup, with similar quantity ratios of the two components to be mixed. A mixture in which a main gas is only mixed with a harmful gas in the ppm range or even in the ppT range is not achievable with this mixing unit since nanograms cannot be dosed with conventional valves and Coriolis sensors, so that a sufficiently accurate dosing is not possible. Even when using modern microelectronic dosing units, only about 0.1 ml/minute can be dosed accurately; the dosing error increases significantly for smaller quantities. Conversely, when smaller metering units are used, it is no longer possible to add larger quantities. Continuous dosing and measuring is furthermore not possible with the known setup. Continuous mixing with a change of concentrations during operation is also not feasible.

### SUMMARY

An aspect of the present invention is therefore to always be able to mix very precisely the desired concentrations down to the ppm, ppb or ppt range, irrespective of the proportion of the supplementary gas to be added. A further aspect of the present invention is to be able to carry out measurements continuously and to generate correspondingly accurate mixtures continuously. A further aspect of the present invention is to be able to change the mixing ratio during the measurement.

An aspect of the present invention provides a metering unit for generating a mixed gas. The metering unit includes a main gas source which provides a main gas, a main gas line which conveys the main gas, a main gas branch line which is configured to convey the main gas from the main gas source and in which is arranged a first mass flow controller, a supplementary gas source which is configured to provide a supplementary gas, a supplementary gas line which is configured to convey the supplementary gas and in which is arranged a second mass flow controller, a first storage tank which is connected to the main gas branch line and to the supplementary gas line and in which is stored the mixed gas comprising the main gas and the supplementary gas, a vent line which is configured to discharge the mixed gas from the first storage tank, a check valve or a pressure relief valve comprising a defined opening pressure arranged in the vent line, a mixed gas line which is configured to convey the mixed gas from the first storage tank and in which is arranged a third mass flow controller, and a mixing zone which is fluidically connected to the mixed gas line and to the main gas line so that the main gas flows from the main gas line and the mixed gas flows from the mixed gas line into the mixing line so as to provide a measuring gas. The mixing zone is configured to lead the measuring gas to a consumer via an outlet line.

### BRIEF DESCRIPTION OF THE DRAWINGS

The present invention is described in greater detail below on the basis of embodiments and of the drawings in which:

FIG. 1 shows a flow diagram of a metering unit according to the present invention;

FIG. 2 shows a flow diagram of a second alternative metering unit according to the present invention;

FIG. 3 shows a flow diagram of a third metering unit according to the present invention; and

FIG. 4 shows a flow diagram of a fourth metering unit according to the present invention.

### DETAILED DESCRIPTION

The metering unit has a main gas source and at least one supplementary gas source via which the gas to be admixed is supplied. The main gas is conveyable into a main gas line and an auxiliary main gas line in which a first mass flow controller is arranged. The supplementary gas is conveyable into a supplementary gas line in which a second mass flow controller is arranged. The main gas branch line and the supplementary gas line either open individually into a storage tank or are brought together upstream of the storage tank, so that the mixed gas flows into the storage tank, which is correspondingly connected either directly or indirectly to the main gas branch line and the supplementary gas line and in which the mixed gas from the main gas and the supplementary gas is stored. The storage tank is additionally fluidically connected to a vent line, via which the mixed gas can be discharged from the storage tank, and in which a check valve or pressure relief valve with a defined opening pressure is arranged. A mixed gas line, via which the mixed gas can be conveyed out of the storage tank and in which a third mass flow controller is arranged, furthermore leads out of the storage tank into a mixing zone. The main gas line also opens into this mixing zone so that at least the main gas from the main gas line and the mixed gas from the mixed gas line flow into the mixing zone and form at least a part of a sample gas which flows via an outlet line to a consumer which is, for example, a fuel cell. This means that there is a two-stage design of the metering unit in which a first mixing ratio is produced in a first stage and additional dilution is carried out in the second stage by adding the main gas. These two stages allow for very precise mixing ratios to be achieved down to the ppt concentration range of the supplementary gas in the main gas. Pure gases can thus also be used as supplementary gases, which are correspondingly not diluted with nitrogen, since the low concentrations can be achieved at the metering unit itself. By using the check valve or the pressure relief valve, the pressure in the storage tank can always be kept constant by constantly discharging some mixed gas via the vent line. This maintains a constant mass flow of the mixing gas so that a constant mixing ratio can be maintained in the mixing zone and the desired mixing ratios can be continuously set and changed during operation. The check valve and the resulting continuous flow also prevent segregation of the gases. Depending on the application, hydrogen as well as nitrogen or oxygen can be used as the main gas, to which carbon dioxide, carbon monoxide, inert gases, or the like, are added as the supplementary gas.

The mixing zone can, for example, be formed upstream of or in a buffer tank in which the sample gas is stored, whereby even in the event of sudden changes in consumption, the desired mixed gas flows with the defined concentrations can nevertheless be continuously supplied to the outlet line. The buffer tank cushions changes in consumption and must be designed to be large enough for this purpose so that an incorrect dosing occurring during a change in flow rate due to subsequent control remains negligible.

It is furthermore advantageous if the buffer tank is connected to a recirculation line via which the sample gas can be led out of the buffer tank and back in again and in which a gas analyzer for the supplementary gas is arranged, whereby the mixing accuracy can be additionally increased, since the proportion of the supplementary gas in the finished mixed gas can be determined and readjusted accordingly. The flow also prevents a segregation of the gases in the buffer tank.

In an embodiment of the present invention, an outlet pressure regulator can, for example, also be arranged in the outlet line so that a mixed gas flow is supplied to the fuel cell at a constant pressure, and unwanted pressure or resulting mass flow fluctuations are avoided.

A check valve can, for example, also be arranged in the main gas line between the main gas source and the buffer tank so that a backflow of the mixed gas to the main gas source is prevented. A pure main gas is accordingly supplied to the buffer tank and a necessary pressure difference is provided for the mass flow controllers.

A particularly advantageous embodiment of the present invention provides that the metering unit has a plurality of main gas branch lines, each having a first mass flow controller, and a plurality of supplementary gas lines, each of which is connected to a different supplementary gas source and in each of which a second mass flow controller is arranged, one of the main gas branch lines and one of the supplementary gas lines being connected in each case to a storage tank, which is connected in each case to a venting line, in which a check valve or pressure relief valve is arranged, via which the respective mixed gas can be discharged from the storage tank, and is connected in each case to a mixed gas line, via which the respective mixed gas can be conveyed out of the respective storage tank and in which in each case a third mass flow controller is arranged, all the mixed gas lines opening into the mixing zone with the main gas line. A plurality of different supplementary gases can thus be generated in parallel as premixed gases and supplied to the main gas flow in the main gas line. Any number of supplementary gases can accordingly be admixed and so that different air compositions can, for example, be concretely mixed. All mixed gases are generated continuously.

To simplify the design, the main gas branch lines are all connected to the one main gas source so that multiple main gas sources are not required; only multiple branches need to be provided.

In a more advanced embodiment of the present invention, a second storage tank with a vent line can, for example, be arranged between the mixing zone and the first storage tank, in which a check valve or pressure relief valve is arranged and into which the first mixed gas line and a second main gas branch line open, and which is connected to the mixing zone via a second mixed gas line. This construction creates a third mixing stage, so that extremely small concentrations of the supplementary gas can be produced in the mixed gas without having to use extremely finely controlled mass flow controllers for this purpose, since its proportion in the main gas decreases with each stage. Any number of further stages can be connected downstream of this structure, whereby concentrations in the ppt range can already be produced by this third stage, so that the detectable limits can already be reached.

For a reliably adjustable mixing ratio over all three stages, which can also be changed continuously, a mass flow controller is arranged in each of the second main gas branch line, the first mixed gas line, and the second mixed gas line.

It can furthermore be advantageous if a vent line branches off from the mixing zone of the sample gas in which a check valve or pressure relief valve is arranged. Such a check valve enables a continuous operation of the metering unit. This is particularly interesting if the supplementary gas is admixed to a low-cost main gas stream, for example, on the oxygen side of the fuel cell unit, since losses of the main gas are here acceptable. A buffer tank can then be dispensed with and it is still possible to obtain a very fast-responding, maximally accurate operation with a small space requirement.

In a more advanced embodiment of the present invention, a gas analyzer for each supplementary gas can, for example, be arranged in the vent line upstream of the check valve so that an accurate analysis of the composition of the gas flow is here also possible.

It is thereby advantageous if an outlet pressure regulator is arranged in the main gas line between the main gas source and the buffer tank or the check valve, which regulates the pressure of the main gas source downwards, for example, by about 1 bar, so that a pressure reserve is available for filling the buffer tank in the event of jumps in consumption. The outlet pressure regulator prevents pressure fluctuations in the main gas source from having a feedback effect on the metering unit.

A metering unit for generating mixed gas is thus provided with which both very small concentrations of a gas to be admixed in the main gas stream of up to below ppt (parts per trillion) proportions can be mixed and mixtures can be produced in quantities of the same order of magnitude. These mixtures may comprise any number of different gases and may, for example, be continuously mixed, with the proportions of the components being continuously changed. Since very small quantities can be admixed relative to the total quantity, a pure gas source, for example, comprising a gas cylinder, can be used despite the possibility of continuous operation. A mixed gas of constant composition can also be continuously generated for subsequent measurement even in the case of larger consumption jumps of the gas.

An embodiment of a metering unit according to the present invention for generating a mixed gas is described below with reference to the drawings.

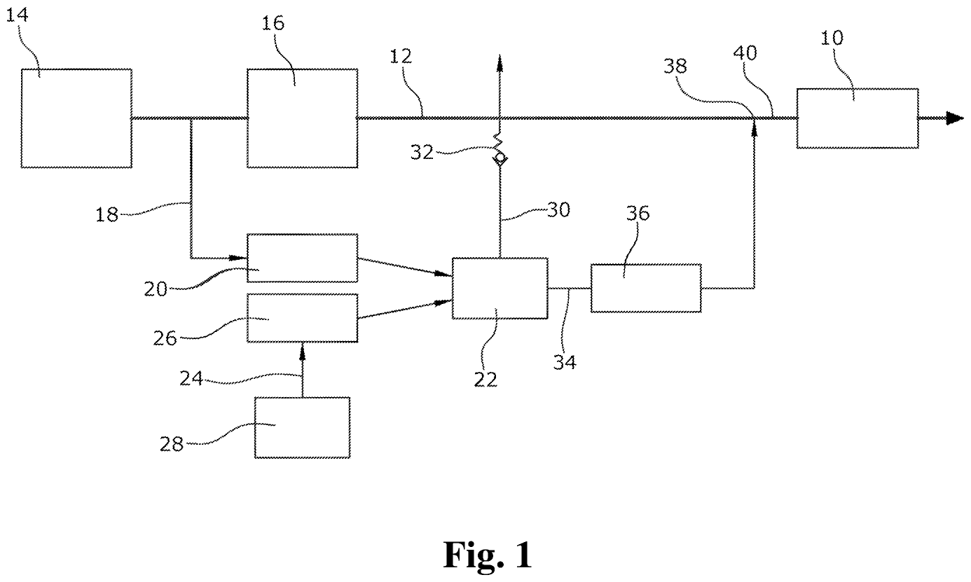

The metering unit according to the present invention shown in FIG. 1 is used for mixing hydrogen as the main gas with carbon monoxide as an additional gas, which is mixed with the hydrogen in small quantities in order to be able to assess its effect on a fuel cell stack as the consumer 10 to be tested.

For this purpose, the consumer 10 is fluidically connected via a main gas line 12 to a main gas source 14 in which the hydrogen is contained. A mass flow measuring and pressure regulating unit 16 is arranged in the main gas line 12, in which the pressure of the main gas source 14 is regulated down to the constant pressure required for the consumer 10 designed as a fuel cell unit and a corresponding mass flow is made available for the anode side of the consumer 10.

The main gas source 14 is additionally connected via a main gas branch line 18, which branches off from the main gas line 12 and in which a first mass flow controller 20 is arranged, to a storage tank 22, which in the present embodiment is designed as a gas divider tube and which has a correspondingly small volume, which may, for example, correspond only to the piping of the gas divider. Due to this very small volume, a change in composition is immediately available, whereas an excessively large storage tank would dampen a change in concentration and could possibly have a segregating effect.

The storage tank 22 is additionally connected via a supplementary gas line 24, in which a second mass flow controller 26 is arranged, to an supplementary gas source 28, in which the gas to be admixed, for example, carbon monoxide, is stored. Two controlled mass flows are supplied to the storage tank 22 by the mass flow controllers 20, 26 so that a mixed gas with a defined mixing ratio is supplied to the storage tank 22.

A vent line 30 leads from the storage tank 22 to the outside, in which vent line 30 a check valve 32 is arranged so that the mixed gas can always be supplied to the storage tank 22 with an equal mass flow and a constant pressure, continuously and independently of the consumption of the mixed gas. The mixed gas is delivered into a first mixed gas line 34 via a third mass flow controller 36 and into a mixing zone 38, where the first mixed gas line 34 opens into the main gas line 12 where the main gas flow mixes with the mixed gas flow. In operation, the check valve 32 is continuously open so that the unneeded generated mixed gas stream is continuously discharged. A two-stage dilution of the supplementary gas with the mixed gas is accordingly established to generate the sample gas. This sample gas is supplied via an outlet line 40 to the consumer 10, i.e., in the present exemplary embodiment, to the fuel cell unit, and can be continuously changed by changing the mass flows in the main gas branch line 18 and the supplementary gas line 24, whereby, by using a small storage volume of the storage tank 22, this change can be made in very short periods of time. The check valve 32 is in this case continuously open so that a small mixed gas flow is lost via the vent line, but a first mixed gas with a constant pressure is always available.

If, for example, the first mass flow controller 20 is now set to a volume flow of 10l/min and the second mass flow controller 26 is set to a volume flow of 1 ml/min, a mixed gas is produced with a supplementary gas concentration in the storage tank 22 of 100 ppm. If a volume flow of this mixed gas of again 1 ml/min is now mixed with a main flow of also 10l/min, a concentration of the supplementary gas in the range of about 10 ppb is produced.

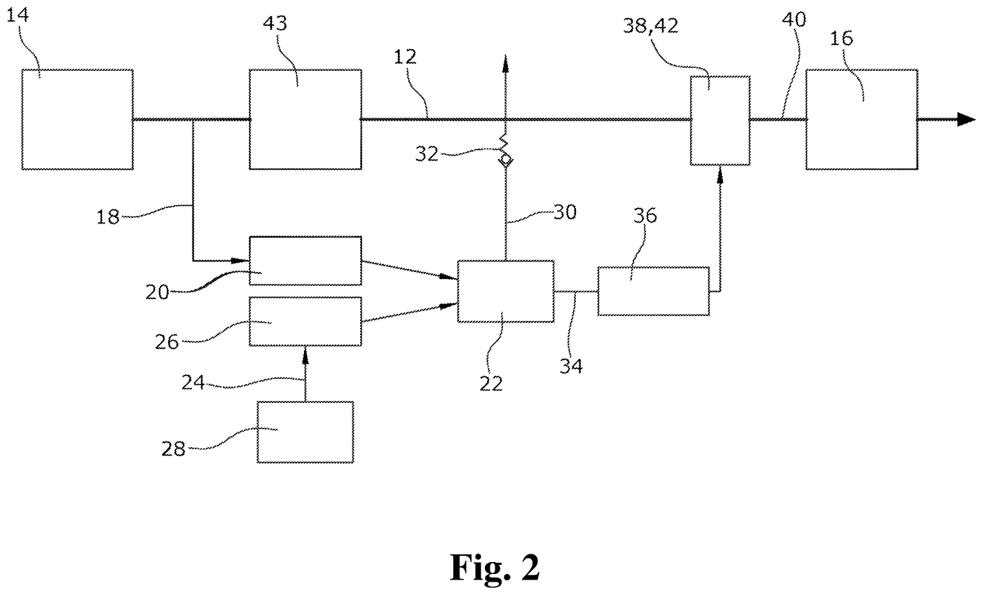

In order to additionally be able to react highly dynamically to changes in consumption of the consumer 10, a buffer tank 42 is arranged in the main gas line 12 upstream of the mass flow measuring and the pressure regulating unit 16, as shown in FIG. 2, in which the sample gas is stored and which forms the mixing zone 38. In the present exemplary embodiment, the mixed gas line is directly connected to the buffer tank 42 therefor. An outlet pressure regulator 43 is also arranged between the buffer tank 42 and the main gas source 14 in the main gas line 12, via which the main gas flow is regulated down to a constant pressure so that no pressure fluctuations occur at the mass flow controllers.

If sudden jumps in consumption of the consumer 10 occur, the three mass flow controllers 20, 26, 36 can only react with a delay so that, without buffer tank 42, the composition of the sample gas would change significantly for a short time. Due to a sufficiently large design of the buffer tank 42, a largely constant concentration is contained in the buffer tank 42 over a certain period of time, even if too little or too much supplementary gas is briefly metered in, because before the concentration in the buffer tank 42 changes measurably, the mass flow controllers 20, 26, 36 again react so that the desired concentration is present in the buffer tank 42 by briefly metering in a somewhat larger or smaller quantity of supplementary gas in order to subsequently have the desired concentration again present in the buffer tank 42. The size of the buffer tank 42 can accordingly be designed depending on the maximum permissible deviation of the concentration.

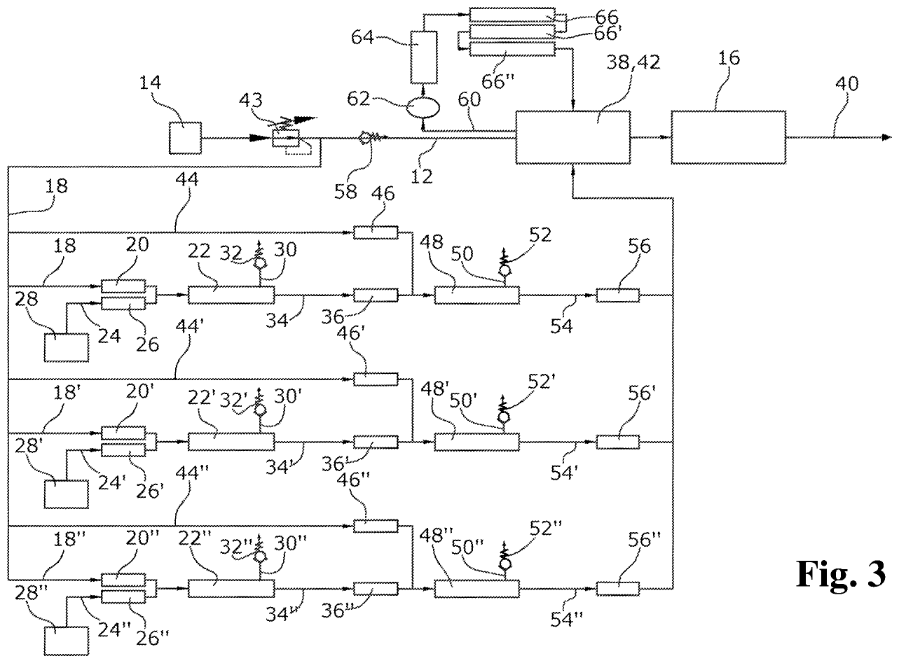

FIG. 3 shows an extended version of the present invention. In this embodiment, several different supplementary gases can be metered to the main gas by connecting several units in parallel. The metering unit accordingly initially comprises three parallel first main gas branch lines 18, 18′, 18″ connected to the main gas source 14. A first mass flow controller 20, 20′, 20″ is arranged in each of these main gas branch lines 18, 18′, 18″. The metering unit also comprises three different supplementary gas lines 24, 24′, 24″ which are connected to different supplementary gas sources 28, 28′, 28″ and in each of which a second mass flow controller 26, 26′, 26″ is arranged. One of each of the main gas branch lines 18, 18′, 18″ and the supplementary gas lines 24, 24′, 24″ open into a first storage tank 22, 22′, 22″ each having a vent line 30, 30′, 30″ in which a check valve 32, 32′, 32″ is arranged. From each of these storage tanks 22, 22′, 22″, the mixed gas flows into a respective first mixed gas line 34, 34′, 34″ in which a respective third mass flow controller 36, 36′, 36″ is arranged.

The metering unit also has a further mixing stage. Three second main gas branch lines 44, 44′, 44″ are connected to the main gas source 14 therefor, in each of which a fourth mass flow controller 46, 46′, 46″ is arranged, which in each case open into an additional second storage tank 48, 48′, 48″, into which in each case also one of the first mixed gas lines 34, 34′, 34″ opens, in each of which the third mass flow controller 36, 36′, 36″ is arranged. This additional second storage tank 48, 48′, 48″ is in turn in each case once again connected to a second vent line 50, 50′, 50″, in each of which a second check valve 52, 52′, 52″ is arranged.

A respective second mixed gas line 54, 54′, 54″, in each of which a respective fifth mass flow controller 56, 56′, 56″ is arranged, leads from the respective additional second storage tank 48, 48′, 48″ to the buffer tank 42. An additional mixing stage is thus provided which makes it possible to supply the additional gas to the main gas in even smaller concentrations and to thus generate a sample gas flow with extremely small concentrations of pollutant gas.

In this embodiment, the buffer tank 42 and thus the mixing zone 38 is connected to the main gas source 14 via the outlet pressure regulator 43 and another check valve 58 in the main gas line 12, the check valve 58 serving to prevent sample gas from flowing from the buffer tank 42 back towards the main gas source and into the main gas branch lines 18, 18′, 18″, 44, 44′, 44″. A recirculation line 60 also leads from the buffer tank 42 via a pump 62 and a gas mixer 64 to three gas analyzers, 66, 66′, 66″, each of which is associated with one of the supplementary gases and can accordingly determine the quantity of these gases in the sample gas in a highly sensitive chemical or physical manner. The mixture of the sample gas in the buffer tank can accordingly be constantly checked and, if necessary, readjusted via the mass flow controllers 20, 20′, 20″, 26, 26′, 26″, 36, 36′, 36″, 46, 46′, 46″, 56, 56′, 56″.

The mass flow measurement and pressure regulating unit 16 is arranged downstream of the buffer tank 42 through which the consumer 10 is supplied with the sample gas.

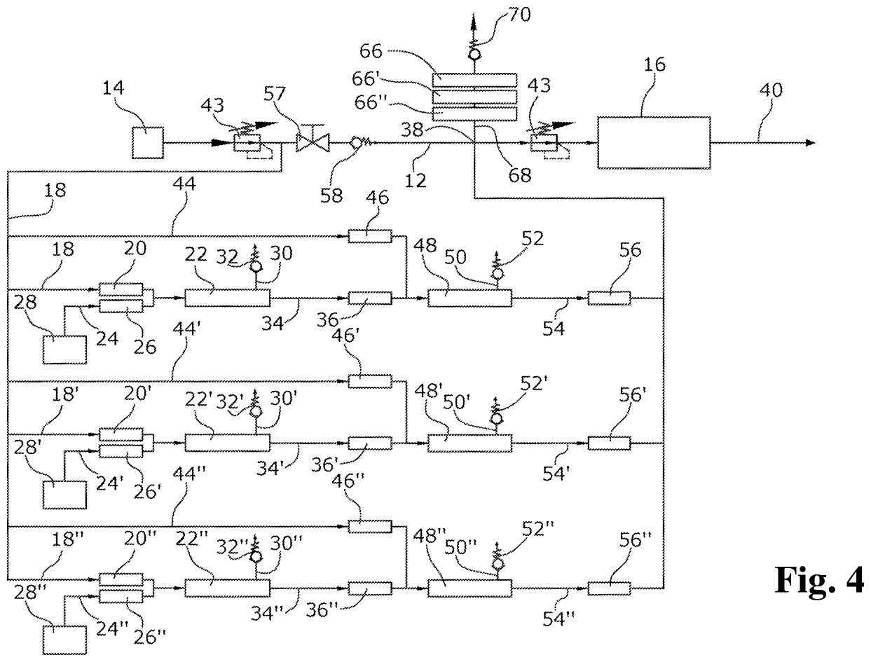

Alternatively, as shown in FIG. 4, it is possible to dispense with the buffer tank 42 and to connect the mixing zone 38 to an additional vent line 68 with a check valve 70, via which any sample gas present in the mixing zone is continuously discharged. An adjustable throttle 57 is in this case arranged upstream of the check valve 58 in the main line 12 downstream of the branching point of the main gas branch line 18, which adjustable throttle 57 may be designed as a needle valve in order to be able to adjust the mass flow in the main line 12 so that no excessive mass flow is lost via the additional vent line 68. A mass flow controller may alternatively be used. In this exemplary embodiment, the gas analyzers 66, 66′, 66″ are arranged in the additional vent line 68 upstream of the check valve 70.

This version is particularly suitable for main gas flows whose gas can be obtained at low cost and is available in sufficient quantities. If this is the case, the metering unit can be controlled with very little delay so that concentrations can be changed at short delay during ongoing measurement operation. If there is a sufficiently large applied pressure gradient and thus a high gas quantity, which is discharged via the check valve 70 and the additional vent line 68, it is also possible to compensate jumps in consumption so that a highly transient operation is achieved in which dosing is maximally accurate. This is of interest, for example, on the cathode side, i.e., the air side of a fuel cell as a consumer 10, since the air can be metered cost-effectively as the main gas flow, whereby the loss via the additional vent line 68 does not interfere. Such a metering unit can furthermore be made very small since the buffer tank can also be dispensed with, thus eliminating the need for larger tanks in the metering unit in which segregation could occur. There is also no need for the recirculation line.

The described embodiments accordingly enable a very precise metering of one or more supplementary gases into a main gas stream due to the multi-stage design, whereby pure gases can be admixed. The high accuracy is achievable both for mixtures in which similar proportions are mixed with each other and for admixtures of one or more supplementary gases in the ppm, ppb or ppt range. According to an embodiment, such a metering unit can, for example, be operated continuously, with concentrations being changed during operation. A concentration can also be kept largely constant in the case of rapidly changing consumption rates. Segregation of the sample gas is also avoided.

It should be clear that the present invention is not limited to the described embodiments, but that various modifications thereof are possible. The check valves can, for example, also be replaced by pressure relief valves which open at a defined pressure. The decisive point is that by using these valves in the vent lines, a mixed gas or measuring gas is always present at a sufficient pressure and thus in the desired quantity, without having to regulate the mass flow after a delay. The number of series-connected circuits and parallel circuits can be adjusted according to the present application. Reference should also be had to the appended claims.

### LIST OF REFERENCE NUMERALS

10 Consumer
12 Main gas line
14 Main gas source
16 Mass flow measuring and pressure regulating unit
18, 18′, 18″ Main gas branch line
20, 20′, 20″ First mass flow controller
22, 22′, 22″ Storage tank/First storage tank
24, 24′, 24″ Supplementary gas line
26, 26′, 26″ Second mass flow controller
28, 28′, 28″ Different supplementary gas source
30, 30′, 30″ Vent line
32, 32′, 32″ Check valve
34, 34′, 34″ First mixed gas line
36, 36′, 36″ Third mass flow controller
38 Mixing zone
40 Outlet line
42 Buffer tank
43 Outlet pressure regulator
44, 44′, 44″ Second main gas branch line
46, 46′, 46″ Fourth mass flow controller
48, 48′, 48″ Additional second storage tank
50, 50′, 50″ Second vent line
52, 52′, 52″ Second check valve
54, 54′, 54″ Second mixed gas line
56, 56′, 56″ Fifth mass flow controller
57 Adjustable throttle
58 Check valve
60 Recirculation line
62 Pump
64 Gas mixer
66, 66′, 66″ Gas analyzer
68 Additional vent line
70 Check valve

What is claimed is:

1-12. (canceled)

13. A metering unit for generating a mixed gas, the metering unit comprising:
a main gas source which provides a main gas;
a main gas line which conveys the main gas;
a main gas branch line which is configured to convey the main gas from the main gas source and in which is arranged a first mass flow controller;
a supplementary gas source which is configured to provide a supplementary gas;
a supplementary gas line which is configured to convey the supplementary gas and in which is arranged a second mass flow controller;
a first storage tank which is connected to the main gas branch line and to the supplementary gas line and in which is stored the mixed gas comprising the main gas and the supplementary gas;
a vent line which is configured to discharge the mixed gas from the first storage tank;
a check valve or a pressure relief valve comprising a defined opening pressure arranged in the vent line;
a mixed gas line which is configured to convey the mixed gas from the first storage tank and in which is arranged a third mass flow controller; and
a mixing zone which is fluidically connected to the mixed gas line and to the main gas line so that the main gas flows from the main gas line and the mixed gas flows from the mixed gas line into the mixing line so as to provide a measuring gas, the mixing zone being configured to lead the measuring gas to a consumer via an outlet line.

14. The metering unit as recited in claim 13, further comprising:
a buffer tank which is configured to store a sample gas,
wherein,
the mixing zone is arranged in or upstream of the buffer tank.

15. The metering unit as recited in claim 14, further comprising:
a recirculation line which is connected to the buffer tank, the recirculation line being configured to lead the sample gas out of the buffer tank and back into the buffer tank; and
a gas analyzer which is configured to analyze the supplementary gas arranged in the recirculation line.

16. The metering unit as recited in claim 13, further comprising:
an outlet pressure regulator arranged in the outlet line.

17. The metering unit as recited in claim 13, further comprising:
a check valve arranged in the main gas line between the main gas source and the buffer tank.

18. A metering unit for generating a mixed gas, the metering unit comprising:
a main gas source which provides a main gas;
a main gas line which conveys the main gas;
a plurality of main gas branch lines each of which is configured to convey the main gas and in each of which is arranged a first mass flow controller;
a plurality of supplementary gas sources each of which is configured to provide a respective supplementary gas which can be different from each other;
a plurality of supplementary gas lines each of which is configured to convey one of the respective supplementary gases and in each of which is arranged a second mass flow controller;
a plurality of first storage tanks, wherein a respective one of the plurality of first storage tanks is connected to a respective one of the plurality main gas branch lines and to a respective one of the plurality of supplementary gas lines and in which is stored a mixed gas comprising the main gas and one of the respective supplementary gases;
a plurality of vent lines, wherein a respective one of the plurality of vent lines is configured to discharge the mixed gas from a respective one of the plurality of first storage tanks;
a plurality of check valves or a plurality of pressure relief valves each of which comprise a defined opening pressure, a respective one of the plurality of check valves or a respective one of the plurality of pressure relief valves being arranged in a respective one of the plurality of vent lines;
a plurality of first mixed gas lines each of which is configured to convey the mixed gas from one of the plurality of first storage tanks and in which is arranged a third mass flow controller; and
a mixing zone which is fluidically connected to each of the plurality of first mixed gas lines and to the main gas line so that the main gas flows from the main gas line and the mixed gas flows from the plurality of first mixed gas lines into the mixing line so as to provide a measuring gas, the mixing zone being configured to lead the measuring gas to a consumer via an outlet line.

19. The metering unit as recited in claim 18, wherein each of the plurality of main gas branch lines are connected to the main gas source.

20. The metering unit as recited in claim 18, further comprising:
a plurality of second main gas branch lines each of which is configured to convey the main gas;
a plurality of second mixed gas lines; and
a plurality of second storage tanks,
wherein,
a respective one of the plurality of second storage tanks is arranged between the mixing zone and a respective one of the plurality of first storage tanks,
each of the plurality of second storage tanks comprises a vent line in which is arranged a check valve or a pressure relief valve and into which a respective one of the plurality of first mixed gas lines and one of the plurality of second main gas branch lines opens, and
each of the plurality of second storage tanks is connected to the mixing zone via a respective one of the second mixed gas lines.

21. The metering unit as recited in claim 20, further comprising:
a fourth mass flow controller which is arranged in a respective one of the plurality of second main gas branch lines; and
a fifth mass flow controller which is arranged in a respective one of the plurality second mixed gas lines.

22. The metering unit as recited in claim 18, further comprising:
a vent line which is arranged to branch off from the mixing zone of a sample gas, the vent line comprising a check valve or a pressure relief valve arranged therein.

23. The metering unit as recited in claim 22, further comprising:
a gas analyzer arranged in the vent line for each one of the respective supplementary gases.

24. The metering unit as recited in claim 18, further comprising:
a check valve arranged in the main gas line; and
an outlet pressure regulator arranged between the main gas source and the check valve in the main gas line.
